(19) United States
(12) Patent Application Publication
(10) Pub. No.: US 2022/0400583 A1
(43) Pub. Date: Dec. 15, 2022

(54) COMPOSITE REFRIGERATION SYSTEM AND DATA CENTER

(71) Applicant: Huawei Digital Power Technologies Co., Ltd., Futian District (CN)

(72) Inventors: Jinliang SONG, Shanghai (CN); Yao ZHENG, Xi'an (CN)

(73) Assignee: Huawei Digital Power Technologies Co., Ltd., Futian District (CN)

(21) Appl. No.: 17/835,170

(22) Filed: Jun. 8, 2022

(30) Foreign Application Priority Data
Jun. 10, 2021 (CN) 202110650465.1

(51) Int. Cl. H05K 7/20

(52) U.S. Cl. CPC H05K 7/20354; H05K 7/20318; H05K 7/20836; H05K 7/20309; H05K 7/20827

(57) ABSTRACT

A composite refrigeration system includes a refrigeration part, a heat dissipation part, a first pipeline, a second pipeline, and a refrigerant. The refrigeration part uses the refrigerant to cool air sent into indoor space, and the heat dissipation part is configured to perform heat dissipation on the refrigerant. In addition, in two heat dissipation modes, the heat exchanger may exchange heat between the refrigerant and a heat carrier in an external pipeline network to implement heat dissipation. The composite refrigeration system implements, by using the heat exchanger, a function of exchanging heat with the external pipeline network, so that heat generated during operation of the composite refrigeration system can be at least partially transferred to the heat carrier in the external pipeline network, to implement the energy recycle and reuse.

### CROSS-REFERENCE TO RELATED APPLICATION

This application claims priority to Chinese Patent Application No. 202110650465.1, filed on Jun. 10, 2021, which is hereby incorporated by reference in its entirety.

### TECHNICAL FIELD

The embodiments relate to the air conditioner refrigeration field, a composite refrigeration system, and a data center equipped with the composite refrigeration system.

### BACKGROUND

For an indoor scenario in which a heat source is provided, especially provided in a centralized manner, heat dissipation processing usually needs to be performed on an area in which the heat source is located. A data center is used as an example. A plurality of servers is arranged in the data center, and these servers generate a large amount of heat during running A refrigeration system of the data center is used to dissipate the heat and cool the data center, to ensure that the server in the data center can run normally in an environment with a preset temperature.

Most of the plurality of servers in the data center are running uninterruptedly. Therefore, the refrigeration system of the data center needs to operate in cooperation with the server for a long time to uninterruptedly dissipate the heat and cool the data center. An existing refrigeration system of a data center cannot effectively recycle heat generated by a cabinet, and long-time operation of the refrigeration system results in a waste of resources.

### SUMMARY

A composite refrigeration system and a data center equipped with the composite refrigeration system may recycle at least a portion of heat generated indoors, to achieve an effect of energy saving and emission reduction.

According to a first aspect, a composite refrigeration system may include a refrigeration part, a heat dissipation part, a first pipeline, a second pipeline, and a refrigerant, where the first pipeline is connected between the refrigeration part and the heat dissipation part, and is configured to send the refrigerant from the heat dissipation part to the refrigeration part; the refrigeration part is connected to indoor space, and is configured to use the refrigerant to cool air sent into the indoor space; and the second pipeline is also connected between the refrigeration part and the heat dissipation part, and is configured to send the refrigerant from the refrigeration part to the heat dissipation part, where the heat dissipation part includes a heat exchanger and a cooler, and the heat dissipation part includes three heat dissipation modes for the refrigerant: in a first heat dissipation mode, the heat dissipation part performs air-cooled heat dissipation on the refrigerant by using the cooler alone; in a second heat dissipation mode, the heat dissipation part exchanges heat between the refrigerant and a heat carrier in an external pipeline network by using the heat exchanger alone, to perform heat dissipation; and in a third heat dissipation mode, the heat dissipation part performs heat dissipation on the refrigerant by simultaneously using the cooler and the heat exchanger.

The composite refrigeration system may form a circulating refrigeration path of the refrigerant through the refrigeration part, the second pipeline, the heat dissipation part, and the first pipeline. When the refrigerant is in the refrigeration part, the refrigerant may be used to cool the air sent into the indoor space, to achieve an effect of reducing an indoor ambient temperature. When the refrigerant flows to the heat dissipation part, the refrigerant may be heat dissipated by using the cooler or the heat exchanger, or simultaneously using the cooler and the heat exchanger, to form three different heat dissipation modes.

The heat exchanger and the external pipeline network form a heat exchange form. When the refrigerant flows through the heat exchanger in a second heat dissipation mode and a third heat dissipation mode, heat exchange may be formed with the heat carrier in the external pipeline network, to implement heat dissipation of the refrigerant and heat transfer to the heat carrier in the external pipeline network at the same time. The external pipeline network may be used as a heating pipe, a hot water pipe, and the like, and correspondingly, the heat carrier may be used as heating, hot water, or the like, thereby implementing energy recycle and reuse.

In a possible implementation, the cooler is a condenser, the condenser is connected in parallel to the heat exchanger, and the condenser is configured to directly perform air-cooled heat dissipation on the refrigerant.

In this implementation, the composite refrigeration system may perform condenser heat dissipation, and the condenser may directly perform air-cooled heat dissipation on the refrigerant. The condenser and the heat exchanger are connected in parallel, so that when the heat dissipation part uses the second heat dissipation mode or the third heat dissipation mode, the refrigerant in the heat exchanger may directly exchange heat with the heat carrier in the external pipeline network.

In a possible implementation, the composite refrigeration system further includes a controller and a first three-way valve. Three ports of the first three-way valve are respectively connected to the second pipeline, the heat exchanger, and the condenser, and the controller controls the first three-way valve to adjust the heat dissipation mode of the heat dissipation part.

In this implementation, the first three-way valve is controlled by the controller. In this way, flow distribution may be performed on a refrigerant flowing into the condenser for heat dissipation and a refrigerant flowing into the heat exchanger for heat exchange, to further control the heat dissipation mode of the heat dissipation part in the composite refrigeration system. Further, a flow quantity of the refrigerant flowing into the heat exchanger is controlled. In this way, a heating temperature of the heat carrier in the external pipeline network may be controlled.

In a possible implementation, the cooler is a dry cooler, the dry cooler is connected in parallel to the external pipeline network, and the dry cooler performs air-cooled heat dissipation on the heat carrier to implement indirect air-cooled heat dissipation on the refrigerant.

In this implementation, the composite refrigeration system may perform dry cooler heat dissipation. After all refrigerants flow through the heat exchanger and complete heat dissipation with the heat carrier in the external pipeline network, the dry cooler may further perform air-cooled heat dissipation on the heat carrier, and further control the heating temperature of the heat carrier, to implement the indirect air-cooled heat dissipation on the refrigerant.

In a possible implementation, the composite refrigeration system further includes a controller and a second three-way valve. Three ports of the second three-way valve are respectively connected to the heat exchanger, the external pipeline network, and the dry cooler, and the controller controls the second three-way valve to adjust the heat dissipation mode of the heat dissipation part.

In this implementation, the second three-way valve is controlled by the controller. In this way, after heat exchange between the refrigerant and the heat carrier is completed, flow distribution may be performed on a heat carrier flowing into the dry cooler for heat dissipation and a heat carrier flowing into a back end of the external pipeline network, to further control the heating temperature of the heat carrier in the external pipeline network of the composite refrigeration system.

In a possible implementation, the composite refrigeration system is provided with a temperature sensor. The temperature sensor is disposed in the indoor space for monitoring a temperature in the indoor space, the temperature sensor is electrically connected to the controller, and the controller controls the first three-way valve or the second three-way valve with reference to a temperature value detected by the temperature sensor.

In this implementation, a temperature rise range of the refrigerant in the refrigeration part may be determined by monitoring an indoor temperature by the temperature sensor. When the indoor temperature is relatively low, a cooling degree of the refrigerant to air sent into the indoor space is relatively low when the refrigerant flows through the refrigeration part, and temperature rise of the refrigerant is relatively low. At this time, heat transferred by the refrigerant to the heat carrier through the heat exchange is relatively low. The controller may increase a flow quantity of a refrigerant flowing into the heat exchanger or decrease a flow quantity of a heat carrier flowing into the dry cooler, to increase the heating temperature of the heat carrier. However, when the indoor temperature is relatively high, the controller decreases the flow quantity of the refrigerant in the heat exchanger or increases the flow quantity of the heat carrier in the dry cooler, to decrease the heating temperature of the heat carrier. In both control manners, the heating temperature of the heat carrier may be kept relatively balanced.

In a possible implementation, the refrigeration part includes an electronic expansion valve, an evaporator, and a compressor that are sequentially connected, the electronic expansion valve is located on a side of the evaporator that is close to the first pipeline, and the compressor is located on a side of the evaporator that is close to the second pipeline.

In this implementation, the evaporator is configured to cool air sent into the indoor space. The electronic expansion valve is configured to reduce pressure of the refrigerant, to facilitate evaporation and heat absorption of the refrigerant in the evaporator. The compressor is configured to compress the refrigerant, to increase the pressure and a temperature of the refrigerant, and restore a liquid state of the refrigerant, thereby facilitating heat exchange efficiency between the refrigerant and the heat carrier.

In a possible implementation, the composite refrigeration system further includes a circulating ventilation channel. An air supply port and an air outlet port of the circulating ventilation channel are separately connected to the indoor space. The refrigeration part is disposed in the circulating ventilation channel and is configured to refrigerate air flowing out of the air outlet port and send refrigerated air into the indoor space through the air supply port.

In this implementation, the circulating ventilation channel may implement air circulation inside the indoor space. After air sent out from the indoor space is cooled by the refrigeration part, low-temperature air is returned to the indoor space, to ensure cleanness of air in the indoor space.

In a possible implementation, a heat exchange core is further disposed in the circulating ventilation channel. The heat exchange core is located between the air outlet port and the refrigeration part, external air flows at the heat exchange core, and the heat exchange core is configured to introduce the external air to perform pre-refrigeration on the air flowing out of the air outlet port.

In this implementation, the heat exchange core may be disposed to pre-refrigerate air in the circulating ventilation channel, to reduce a temperature of air flowing to the refrigeration part, and further reduce power consumption of the composite refrigeration system. At the same time, a temperature of air outside the heat exchange core is lower than a temperature of the refrigerant or the heat carrier in the heat dissipation part, and the air may further assist heat dissipation of the condenser or the dry cooler.

According to a second aspect, a data center may center include an equipment room and the composite refrigeration system provided in the first aspect. The refrigeration part of the composite refrigeration system is connected to indoor space of the equipment room.

In the second aspect, because the equipment room of the data center uses the composite refrigeration system in the first aspect for heat dissipation, the data center also has the foregoing energy recycling function, which is more energy-saving and environment-friendly.

In a possible implementation, the composite refrigeration system includes a controller, the data center includes a server, the controller is further communicatively connected to the server, and the controller further controls a heat dissipation mode of the composite refrigeration system with reference to a workload of the server.

In this implementation, the controller may monitor the workload of the server through being communicatively connected to the server in the data center. When the workload of the server is relatively high, heat generated by the server is relatively high. In this case, the composite refrigeration system needs to increase a refrigerating intensity of the refrigeration part, to make a greater cooling range of air sent into the indoor space and ensure an indoor heat dissipation effect. Because a temperature of the refrigerant is relatively increased, the controller may decrease a flow quantity of a refrigerant in the heat exchanger or increase a flow quantity of the heat carrier in the dry cooler, to reduce a heating temperature of the heat carrier. Conversely, when the workload of the server is relatively low, the flow quantity of the refrigerant flowing into the heat exchanger is increased, or the flow quantity of the heat carrier flowing into the dry cooler is decreased. In both control manners, the heating temperature of the heat carrier may be kept relatively balanced.

### BRIEF DESCRIPTION OF THE DRAWINGS

FIG. 1 is a schematic diagram of an application scenario of a composite refrigeration system;

FIG. 2 is a schematic diagram of a refrigeration path in a composite refrigeration system;

FIG. 3 is a schematic diagram of a refrigeration part in a composite refrigeration system;

FIG. 4 is a schematic diagram of a circulating state of a refrigerant in a composite refrigeration system;

FIG. 5 is a schematic diagram of a structure of a heat dissipation part in a composite refrigeration system;

FIG. 6 is another schematic diagram of a refrigeration path in a composite refrigeration system;

FIG. 7 is another schematic diagram of a heat dissipation part in a composite refrigeration system;

FIG. 8 is another schematic diagram of an application scenario of a composite refrigeration system;

FIG. 9 is another schematic diagram of an application scenario of a composite refrigeration system; and

FIG. 10 is another schematic diagram of an application scenario of a composite refrigeration system.

### DETAILED DESCRIPTION OF THE EMBODIMENTS

The following describes the solutions in the embodiments with reference to the accompanying drawings. It is clear that the described embodiments are merely some but not all of the embodiments. All other embodiments obtained by a person of ordinary skill in the art based on the embodiments without creative efforts shall fall within the scope of the embodiments.

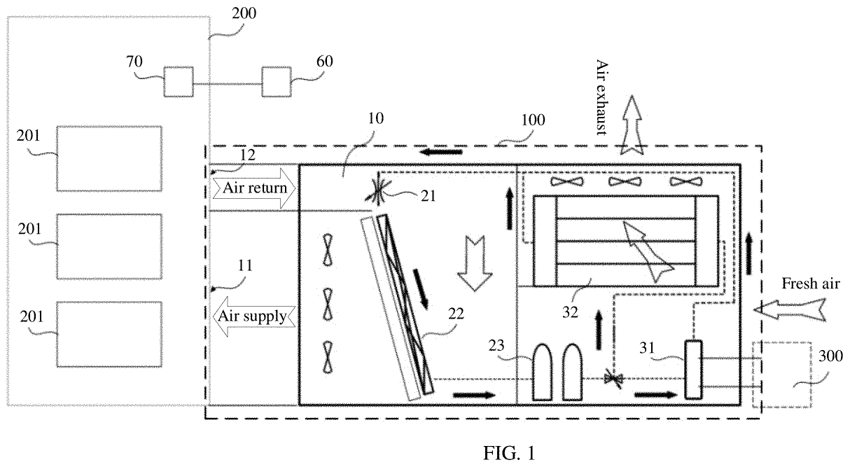

The composite refrigeration system may be used in an indoor environment with a heat source and is applicable to an indoor environment in which the heat source is centrally arranged, for example, may be used in a data center. The following uses a data center as an example for description. FIG. 1 is a schematic diagram of an application scenario of applying a composite refrigeration system 100 in the data center according. The data center includes an equipment room 200, and at least one IT device (for example, a server 201) or/and a power supply apparatus is/are arranged in the equipment room 200. When the at least one IT device or/and the power supply apparatus is/are running, a large amount of heat is generated. The composite refrigeration system 100 in this embodiment is configured to implement refrigeration and heat dissipation of the data center. In this embodiment, the data center may be a micro-modular data center, or may be a prefabricated data center, or may be a floor or room formed in a building and used to place an IT server. Based on the data centers in the foregoing different forms, the composite refrigeration system 100 may be disposed inside the equipment room 200 of the data center, or may be disposed outside the equipment room 200, or may be partially disposed inside the equipment room 200 and partially disposed outside the equipment room 200.

In some implementation scenarios, in addition to the IT device and the power supply apparatus, a concept of the data center further includes a temperature control system and another auxiliary device. Therefore, the composite refrigeration system 100 in this embodiment may also be considered as a part of the data center.

In the illustration of FIG. 1, the composite refrigeration system 100 includes a circulating ventilation channel 10. The circulating ventilation channel 10 includes an air supply port 11 and an air outlet port 12. The air supply port 11 and the air outlet port 12 are separately connected to the equipment room 200 of the data center. The air supply port 11 is configured to send refrigerated air (marked as fresh air in the figure) into the equipment room 200 of the data center. The air outlet port 12 is configured to draw air in the equipment room 200 of the data center into the circulating ventilation channel 10 (marked as return air in the figure) and refrigerate the air.

Thus, the equipment room 200 of the data center and the circulating ventilation channel 10 form a sealed circulating ventilation path. The composite refrigeration system 100 may carry, through air flowing out of the air outlet port 12, heat generated by the server 201 during operation out of the equipment room. The air is refrigerated and heat dissipated by the composite refrigeration system 100 and is sent back to the equipment room from the air supply port 11, to implement overall heat dissipation of the equipment room 200 of the data center. In the embodiment shown in FIG. 1, the air supply port 11 is located below the air outlet port 12. Cold air sent from the air supply port 11 flows upwardly in the equipment room, to balance an air temperature in the equipment room.

In the structure shown in FIG. 1, the entire composite refrigeration system 100 is disposed outside the equipment room 200. However, in some other embodiments, the composite refrigeration system 100 may be alternatively partially disposed inside the equipment room 200, and the circulating ventilation channel 10 may be formed through isolation of space inside the equipment room 200, without affecting implementation and deployment of the solution.

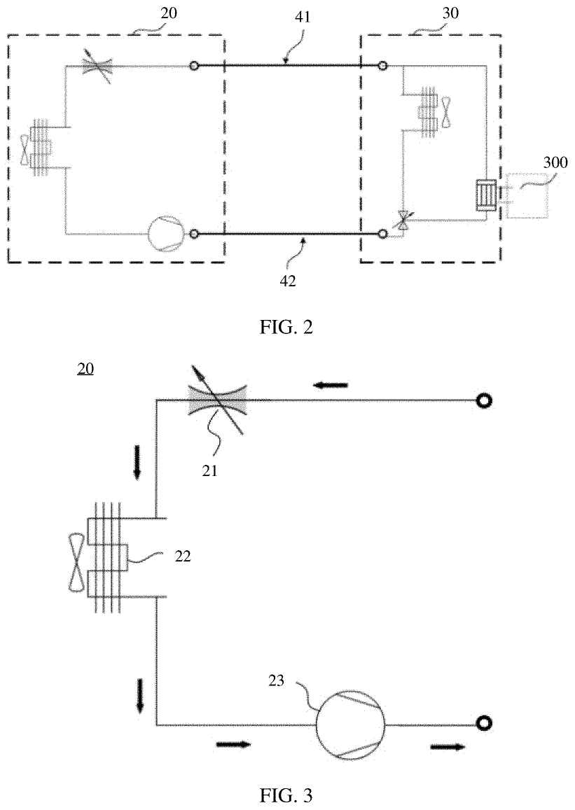

Referring to FIG. 2, the composite refrigeration system 100 includes a refrigeration part 20, a heat dissipation part 30, a first pipeline 41, and a second pipeline 42. The refrigeration part 20, the heat dissipation part 30, the first pipeline 41, and the second pipeline 42 are connected to form a refrigeration path. The composite refrigeration system 100 further includes a refrigerant. The refrigerant flows through the refrigeration path (a black arrow is used to indicate a flow direction of the refrigerant in the figure) to achieve an effect of refrigerating air sent into the equipment room 200 of the data center. The refrigerant may be implemented by using a coolant, such as Freon (fluorine saturated with hydrocarbons, chlorine, and bromide derivatives), an azeotropic mixture (an azeotropic solution of two Freon mixtures), a hydrocarbon (propane, ethylene, and the like), and ammonia. These coolants can implement liquefaction and facilitate refrigeration at a normal temperature or lower temperature.

The first pipeline 41 and the second pipeline 42 are separately connected between the refrigeration part 20 and the heat dissipation part 30. The first pipeline 41 is configured to send the refrigerant from the heat dissipation part 30 to the refrigeration part 20, and the second pipeline 42 is configured to send the refrigerant from the refrigeration part 20 to the heat dissipation part 30. The refrigeration part 20 is disposed in the circulating ventilation channel 10, and is configured to cool and refrigerate, by using the refrigerant, the air sent into the equipment room 200 of the data center. A process in which the refrigerant cools and refrigerates the air may be understood as a process in which the refrigerant exchanges heat with the air. A temperature of the refrigerant that is cooled and refrigerated in the refrigeration part 20 is increased, and the heat dissipation part 30 is configured to dissipate heat of the refrigerant.

Referring to FIG. 3, a structure of the refrigeration part 20 is illustrated. The refrigeration part 20 includes an electronic expansion valve 21, an evaporator 22, and a compressor 23 that are sequentially connected. The evaporator 22 is located between the electronic expansion valve 21 and the compressor 23. The electronic expansion valve 21 is located on a side of the evaporator 22 that is close to the first pipeline 41, and the compressor 23 is located on a side of the evaporator 22 that is close to the second pipeline 42. A refrigerant sent from the heat dissipation part 30 through the first pipeline 41 reaches the evaporator 22 after the refrigerant passes through the electronic expansion valve 21. The refrigerant then flows from the evaporator 22 to the compressor 23 and flows into the heat dissipation part 30 through the second pipeline 42.

The electronic expansion valve 21 is configured to throttle and depressurize the refrigerant, so that the refrigerant is converted from a liquid state to a gas-liquid mixed state. The evaporator 22 is configured to make the refrigerant evaporate and absorb heat, to implement heat exchange between the refrigerant and the air sent into the equipment room 200 of the data center. In other words, the evaporator 22 is configured to cool the air sent into the equipment room 200 of the data center. The compressor 23 is configured to pressurize the refrigerant, so that the refrigerant is converted from the gas-liquid mixed state to a high-temperature liquid state and is sent to the heat dissipation part 30 for heat dissipation. In some embodiments, the compressor 23 may convert a portion of the refrigerant into a liquid state, and formation of the entire liquid state of the refrigerant may also be completed in the heat dissipation part 30.

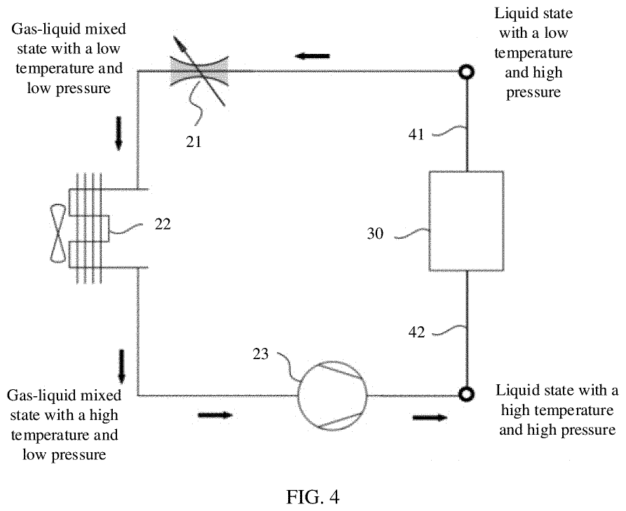

For details, refer to the schematic diagram of a state and a temperature cycle of a refrigerant in a refrigeration path shown in FIG. 4. Because the heat dissipation part 30 is configured to dissipate heat for the refrigerant, a temperature of a refrigerant flowing into the electronic expansion valve 21 from the first pipeline 41 is relatively low. At this time, the refrigerant is in a low-temperature and high-pressure liquid state. After the electronic expansion valve 21 throttles and depressurizes the refrigerant, the refrigerant is converted from a low-pressure liquid state to a low-pressure gas-liquid mixed state, and the temperature is maintained at a low temperature. The evaporator 22 makes the refrigerant evaporate and absorb heat, and then the refrigerant is in a high-temperature and low-pressure gas-liquid mixed state. In some scenarios, the refrigerant is alternatively directly in a high-temperature and low-pressure gas state. The compressor 23 exerts pressure on the refrigerant to convert the refrigerant from a gas state or a gas-liquid mixed state into a high-temperature and high-pressure liquid state. In this way, the refrigerant completes circulation of refrigeration work in the refrigeration path.

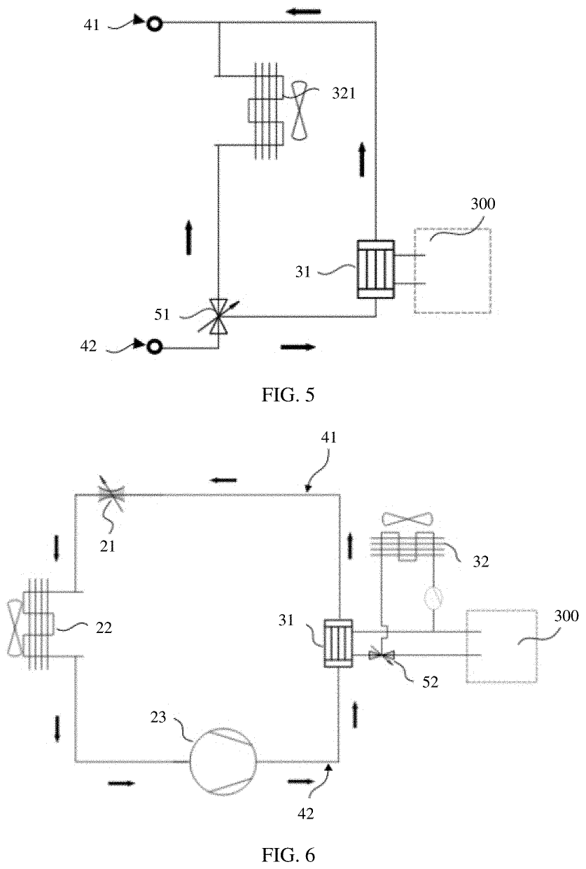

Referring back to FIG. 1 and FIG. 2, and referring to FIG. 5 together, a structure of the heat dissipation part 30 is illustrated. The composite refrigeration system 100 includes a heat exchanger 31 and a cooler 32 on a side of the heat dissipation part 30. The heat dissipation part 30 is configured to perform heat dissipation and cooling on the refrigerant. The heat dissipation part 30 includes three heat dissipation modes: In a first heat dissipation mode, the heat dissipation part 30 performs air-cooled heat dissipation on the refrigerant by using the cooler 32 alone; in a second heat dissipation mode, the heat dissipation part 30 exchanges heat with the external pipeline network 300 by using the heat exchanger 31 alone, and exchanges heat of the refrigerant to the heat carrier in the external pipeline network 300, to implement heat dissipation of the refrigerant; and in a third heat dissipation mode, the heat dissipation part 30 performs heat dissipation on the refrigerant by simultaneously using the heat exchanger 31 and the cooler 32.

In the embodiment shown in FIG. 5, the heat exchanger 31 is connected in parallel to the cooler 32, and the cooler 32 is implemented in a form of a condenser 321. After entering the heat dissipation part 30 from the second pipeline 42, the refrigerant may flow into the condenser 321 or the heat exchanger 31 alone to implement heat dissipation (that is, the first or the second heat dissipation mode), or may be divided in the heat dissipation part 30, where a part flows into the condenser 321 for heat dissipation, and the other part flows into the heat exchanger 31 for heat dissipation. In other words, the heat exchanger 31 and the condenser 321 may be simultaneously used to implement heat dissipation of the refrigerant in the heat dissipation part 30 (that is, the third heat dissipation mode).

When the refrigerant flows into the condenser 321, the condenser 321 is provided with a heat dissipation fin and a fan, so that the refrigerant may be directly heat dissipated through air cooling. In this embodiment, the heat exchanger 31 is disposed opposite to the external pipeline network 300. When flowing through the heat exchanger 31, the refrigerant may implement heat exchange with the external pipeline network 300. A heat carrier (not shown in the figure) flows in the external pipeline network 300, and the external pipeline network 300 and the heat exchanger 31 form a heat exchange connection structure. In some embodiments, the heat exchanger 31 may be implemented in a form of a plate heat exchanger. When flowing through the heat exchanger 31, the refrigerant may implement heat exchange with the heat carrier in the external pipeline network 300. A high temperature of the refrigerant may be transferred to the heat carrier with a relatively low temperature. After the refrigerant heats the heat carrier, a temperature of the refrigerant is relatively decreased to achieve a heat dissipation effect, and a temperature of the heat carrier is relatively increased. The external pipeline network 300 may be connected to a local heating pipe, a hot water pipe, or the like. Correspondingly, the heat carrier may be water, and may be used as heating water or domestic hot water.

In the composite refrigeration system 100, when the equipment room 200 of the data center is refrigerated and heat dissipated, at least a portion of heat generated in a refrigeration process can be transferred to the external pipeline network 300 by using the heat exchanger 31, to implement energy recycle and reuse. Compared with another solution of an embodiment in which the refrigerant is directly heat dissipated by using the cooler 32 alone, the composite refrigeration system 100 has more energy-saving and environment-friendly effects.

For example, it is calculated that heat generated by the composite refrigeration system 100 for one hour of refrigeration is 80 kWh. After operating in the second heat dissipation mode for two hours, the composite refrigeration system 100 may provide 160 kWh of heat to the external pipeline network 300. After operating in the second heat dissipation mode throughout a day, the composite refrigeration system 100 may provide 1920 kWh of heat to the external pipeline network 300. The heat may produce a better heating effect for the external pipeline network 300. In the illustration of FIG. 5, the composite refrigeration system 100 further includes a first three-way valve 51. The first three-way valve 51 is connected between the second pipeline 42, the heat exchanger 31, and the condenser 321, and is configured to adjust a heat dissipation mode of the heat dissipation part 30. The first three-way valve 51 has a first liquid inlet port and two first liquid outlet ports. The first liquid inlet port is connected to the second pipeline 42, one first liquid outlet port is connected to the condenser 321, and the other first liquid outlet port is connected to the heat exchanger 31. Therefore, a refrigerant in a high-temperature liquid state is sent from the compressor 23 may enter the first three-way valve 51 from the first liquid inlet port, and then flow to the condenser 321 and the heat exchanger 31 from the two first liquid outlet ports respectively. It may be understood that a flow quantity of the refrigerant flowing into the first three-way valve 51 from the first liquid inlet port is equal to or nearly equal to a sum of flow quantities of refrigerants flowing out of the first three-way valve 51 from the two first liquid outlet ports. In other words, a sum of flow quantities of refrigerants flowing through the condenser 321 and the heat exchanger 31 is the same as a flow quantity in the second pipeline 42.

In some embodiments, respective flow quantities of the two first liquid outlet ports of the first three-way valve 51 may be adjusted. The composite refrigeration system 100 is further provided with a controller 60 (refer to FIG. 1). The controller 60 is electrically connected to the first three-way valve 51 and is configured to control operation of the first three-way valve 51. The controller 60 may control the first three-way valve 51, to distribute a flow quantity of a refrigerant flowing into the heat exchanger 31 and a flow quantity of a refrigerant flowing into the condenser 321.

The controller 60 may distribute the flow quantity of the refrigerant based on a heat dissipation requirement of the refrigerant or based on a heating temperature required by the heat carrier. For example, when heat dissipation effects of the condenser 321 and the heat exchanger 31 are different, if the refrigerant needs to obtain a better heat dissipation effect, the controller 60 may control the first three-way valve 51, so that more of the refrigerant flows through a path with a better heat dissipation effect. In this way, a refrigerant with a larger flow quantity can obtain better heat dissipation. For example, when the heat dissipation effect of the condenser 321 is better than that of the heat exchanger 31, the controller 60 may control the first three-way valve 51, so that more of the refrigerant flows out of the first liquid outlet port connected to the condenser 321 and enters the condenser 321 to obtain better heat dissipation. Correspondingly, in this case, a flow quantity of a refrigerant flowing into the heat exchanger 31 from the first liquid outlet port is relatively decreased, and a heating effect of the heat exchanger 31 on the heat carrier is decreased accordingly.

In some embodiments, the controller 60 may further control a difference in the heat dissipation effects between the condenser 321 and the heat exchanger 31 by controlling a fan speed of the condenser 321 or controlling a flow rate of the heat carrier in the external pipeline network 300. That the controller 60 controls the flow rate of the heat carrier in the external pipeline network 300 may be implemented as that the controller 60 directly controls the external pipeline network 300, or that the controller 60 is communicatively connected to a control system of the external pipeline network 300, and the controller 60 indirectly controls the flow rate of the heat carrier. In addition, the heat dissipation effect of the condenser 321 may be worse than a heat exchange effect of the heat exchanger 31. In this scenario, when the refrigerant needs to implement better heat dissipation, the controller 60 needs to control more of the refrigerant to flow into the heat exchanger 31.

The controller 60 controls distribution of the flow quantity of the refrigerant based on the heating temperature required by the heat carrier. This may be implemented based on the following scenario: on a premise that the flow rate of the heat carrier in the external pipeline network 300 is given, if an external ambient temperature is relatively low, an initial temperature of the heat carrier is lower before the heat carrier exchanges heat with the refrigerant at the heat exchanger 31. In this case, through control of the controller 60, a flow quantity of a refrigerant flowing into the heat exchanger 31 is larger, and a temperature of heating the heat carrier by the refrigerant is increased, so that an increasing range of a temperature obtained after heat exchange is performed on the heat carrier is larger. If the external ambient temperature is relatively high, the initial temperature of the heat carrier increases accordingly. In this case, through control of the controller 60, a flow quantity of the refrigerant flowing into the heat exchanger 31 may be smaller, and the temperature of heating the heat carrier by the refrigerant is decreased, so that the increasing range of the temperature obtained after heat exchange is performed on the heat carrier is smaller.

The foregoing application scenario related to the external ambient temperature may be used to seasonally adjust a heat dissipation manner of the composite refrigeration system 100. For example, in winter when the external ambient temperature is relatively low, the controller 60 may control more of the refrigerant to flow into the heat exchanger 31, or control all the refrigerant to flow into the heat exchanger 31, so that the heat carrier with a relatively low temperature in the external pipeline network 300 obtains a greater temperature rise through heat exchange; while in summer when the external ambient temperature is relatively high, the controller 60 may control more of the refrigerant to flow into the condenser 321, or control all the refrigerant to flow into the condenser 321, so that the heat carrier with a relatively high temperature in the external pipeline network 300 obtains a smaller temperature rise or a temperature rise of zero through exchange. It may be understood that when the external pipeline network 300 is a heating pipeline network, the external pipeline network 300 does not need to operate in summer, and therefore the heat carrier does not need to form heat exchange with the composite refrigeration system 100. When the external pipeline network 300 is a hot water pipe, an amount of hot water used in summer and a temperature of use are decreased accordingly, and the heating temperature required by the heat carrier is also decreased accordingly.

In an embodiment, still referring to FIG. 1, the composite refrigeration system 100 is further provided with a temperature sensor 70. The temperature sensor 70 is disposed in the equipment room 200 of the data center and is configured to monitor a temperature in the equipment room 200 of the data center. The temperature sensor 70 is communicatively connected to the controller 60 to transmit a detected temperature value of the equipment room 200 of the data center to the controller 60. After receiving the temperature value, the controller 60 may control the first three-way valve 51 to distribute a flow quantity of the refrigerant.

In this embodiment, a real-time temperature value of the equipment room 200 of the data center detected by the temperature sensor 70 may be used to determine a range of cooling, by the refrigeration part 20, air sent into the equipment room 200 of the data center. When the temperature of the equipment room 200 of the data center is relatively low, the range of cooling the air by the refrigeration part 20 by using the refrigerant is also decreased accordingly. In this case, heat absorbed by a refrigerant in the refrigeration part 20 through evaporation is also decreased accordingly, and a temperature rise range of the refrigerant in a refrigeration process is decreased accordingly. Therefore, heat that can be supplied by the refrigerant to the heat carrier through exchange in the heat exchanger 31 is decreased accordingly, and a heating effect of the heat carrier is reduced. In this case, the controller 60 controls the first three-way valve 51, so that more of the refrigerant may be distributed to flow into the heat exchanger 31, and further, more exchangeable heat is provided for the heat carrier, to maintain a heating effect of the refrigerant on the heat carrier. Conversely, when the real-time temperature value of the equipment room 200 of the data center detected by the temperature sensor 70 is relatively high, the heat that can be supplied by the refrigerant to the heat carrier in the heat exchanger 31 is increased. In this case, the controller 60 controls the first three-way valve 51, so that more of the refrigerant may be distributed to flow into the condenser 321 for direct heat dissipation, less exchangeable heat is provided by the refrigerant in the heat exchanger 31, and the heating effect of the refrigerant on the heat carrier is more balanced.

In an embodiment, the controller 60 is alternatively communicatively connected to the server 201 in the equipment room 200 of the data center for monitoring a real-time workload of the server 201 and then controlling flow distribution of a refrigerant in the first three-way valve 51 based on the workload. The temperature in the equipment room 200 of the data center is further related to the workload of the server 201. When the workload of the server 201 is relatively heavy, heat generated when the server 201 operates is relatively high, and the composite refrigeration system 100 needs to increase a refrigerating intensity of the server 201, to reduce a temperature of air sent into the equipment room 200 of the data center. In this way, an ambient temperature in the equipment room 200 of the data center is relatively balanced. The ambient temperature is not increased accordingly with an increase of the workload of the server 201, and operation efficiency of the server 201 is not affected. It may be understood that a refrigerating intensity of the composite refrigeration system 100 is increased, and a temperature of a refrigerant flowing out of the refrigeration part 20 is also increased accordingly. In this case, the controller 60 needs to distribute more of the refrigerant to the condenser 321 for heat dissipation, to reduce a flow quantity of the refrigerant in the heat exchanger 31. Such control may make heat supplied by the refrigerant in the heat exchanger 31 to the heat carrier relatively constant. The heat carrier does not obtain more heat with an increase of a temperature of the refrigerant, and it is ensured that the heat carrier achieves a more balanced heating effect. Conversely, when the workload of the server 201 is relatively low, relatively less heat is generated in an operation process of the server 201, and a refrigerating intensity of the refrigeration part 20 on the air by using the refrigerant is decreased. In this case, the controller 60 may distribute more of the refrigerant to flow into the heat exchanger 31, to maintain the heating effect of the refrigerant on the heat carrier.

Because there may be a plurality of servers 201 in the equipment room 200 of the data center, that the controller 60 is communicatively connected to the server 201 may be that the controller 60 is separately communicatively connected to the plurality of servers 201, and separately monitors workloads of the servers 201. Finally, a flow quantity of the refrigerant is distributed in a manner of calculating an average value. In some other embodiments, the controller 60 may be alternatively communicatively connected to only one or some of the servers 201 in the equipment room 200 of the data center and distribute the flow quantity of the refrigerant based on a workload of the one or some of the servers 201. All the foregoing implementations may ensure that the heating effect of the refrigerant on the heat carrier in the external pipeline network 300 is consistent when the composite refrigeration system 100 operates effectively.

In some other implementations, the controller 60 may alternatively receive the temperature value obtained through monitoring by the temperature sensor 70 and workload data of the server 201 at the same time, and distribute a flow quantity of the refrigerant in the heat dissipation part 30 based on the temperature value in the equipment room 200 of the data center and a workload status of the server 201 at the same time, to ensure a refrigerating effect of the composite refrigeration system 100 and the heating effect on the heat carrier at the same time.

It should be noted that, in the foregoing embodiment, the first three-way valve 51 may be alternatively replaced with two solenoid valves (not shown in the figure). One solenoid valve is connected between the second pipeline 42 and the condenser 321, and the other solenoid valve is connected between the second pipeline 42 and the heat exchanger 31. The controller 60 is configured to simultaneously control the two solenoid valves to be linked and may also have the foregoing effect of distributing a flow quantity of the refrigerant.

In addition, when the composite refrigeration system 100 is applied to another operation scenario other than the data center, the controller 60 may also be communicatively connected to a heat source in the another operation scenario, and accordingly adjust flow distribution of the refrigerant by monitoring a workload of the heat source in real time, to achieve a corresponding effect of controlling the heat dissipation mode of the heat dissipation part 30.

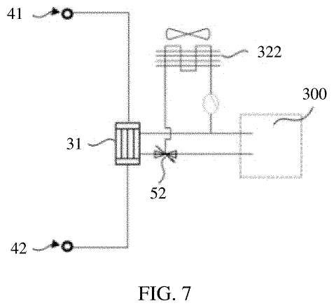

For illustration of another embodiment of the composite refrigeration system 100, refer to FIG. 6 and FIG. 7. In this embodiment, a structure of the refrigeration part 20 is consistent with that of the embodiment described above, and the cooler 32 of the heat dissipation part 30 is implemented by using a dry cooler 322. In the heat dissipation part 30, the dry cooler 322 is connected in parallel to the external pipeline network 300, and a medium flowing in the dry cooler 322 is a heat carrier, instead of the refrigerant in the embodiment described above. The dry cooler 322 also includes a heat dissipation fin and a fan and may perform air-cooled heat dissipation on the heat carrier to achieve an indirect heat dissipation effect on a refrigerant in the heat dissipation part 30.

The heat dissipation part 30 also includes the heat exchanger 31, and the heat exchanger 31 is connected between the second pipeline 42 and the first pipeline 41 and is also disposed opposite to the external pipeline network 300. When flowing through the heat exchanger 31, the refrigerant may implement heat exchange with the heat carrier in the external pipeline network 300. In this embodiment, the refrigerant is directly heat dissipated only by using the heat exchanger 31, and the heat is transferred to the heat carrier. The dry cooler 322 is connected in parallel to the external pipeline network 300. The heat carrier that completes heat exchange with the refrigerant may flow directly into a rear end of the external pipeline network 300 or may flow into the dry cooler 322 at least partially. After the dry cooler 322 performs air-cooled heat dissipation on the heat carrier, the heat carrier then flows into the rear end of the external pipeline network 300. By controlling a flow quantity of a heat carrier flowing into the dry cooler 322, a heat dissipation effect of the dry cooler 322 on the heat carrier may be controlled, so that the heat dissipation effect is formed on the refrigerant when the heat carrier obtained after being heat dissipated performs heat exchange with the refrigerant again. In other words, in this embodiment, the dry cooler 322 indirectly controls a heat dissipation effect of the refrigerant by controlling heat dissipation of the heat carrier.

In the composite refrigeration system 100 in this embodiment, when the heat carrier flows only in the external pipeline network 300 and does not enter the dry cooler 322 for heat dissipation (that is, the second heat dissipation mode), all heat in the refrigerant is exchanged to the heat carrier. In this way, an energy recycling efficiency of the composite refrigeration system 100 is relatively high, and a heating effect on the heat carrier is relatively strong. However, when all the heat carrier enters the dry cooler 322 for heat dissipation (that is, the first heat dissipation mode), a temperature of the heat carrier flowing into the rear end of the external pipeline network 300 is lower, or the heat exchanger 31 and the dry cooler 322 directly form a heat dissipation path. The composite refrigeration system 100 no longer conveys the heat carrier to the external pipeline network 300. In this case, the energy recycling efficiency of the composite refrigeration system 100 is relatively low.

In an embodiment, the composite refrigeration system 100 further includes a second three-way valve 52. The second three-way valve 52 is connected between the heat exchanger 31, the external pipeline network 300, and the dry cooler 322, and is configured to control the flow quantity of the heat carrier flowing into the dry cooler 322 for heat dissipation and distribution of a flow quantity of the heat carrier flowing into the rear end of the external pipeline network 300, that is, control the heat dissipation mode of the heat dissipation part 30. The second three-way valve 52 includes one second liquid inlet port and two second liquid outlet ports. The second liquid inlet port is connected to the heat exchanger 31, one second liquid outlet port is connected to the dry cooler 322, and the other second liquid outlet port is connected to the rear end of the external pipeline network 300. Therefore, the heat carrier that completes heat exchange from the heat exchanger 31 may flow into the second three-way valve 52 through the second liquid inlet port, and flow into the dry cooler 322 through the second liquid outlet port for heat dissipation, or directly flow into the rear end of the external pipeline network 300 through the other second liquid outlet port separately.

Similar to the embodiments shown in FIG. 2 and FIG. 5, the composite refrigeration system 100 may also implement distribution of a flow quantity of a heat carrier flowing through the dry cooler 322 and a flow quantity of a heat carrier directly flowing into the rear end of the external pipeline network 300 by controlling the second three-way valve 52 by the controller 60, to achieve an effect of simultaneously controlling heat dissipation of the dry cooler 322 and controlling a heating temperature of the heat carrier. It may be understood that the controller 60 may control the second three-way valve 52 based on a heat dissipation requirement of the heat carrier or based on a heating temperature required by the heat carrier. When the heat carrier needs to be heat dissipated more, the controller 60 may control more of the heat carrier to flow into the dry cooler 322, so that more of the heat carrier can be heat dissipated by using the dry cooler 322. The controller 60 may also control more of the heat carrier to flow toward the rear end of the external pipeline network 300 when the external pipeline network 300 requires more heat. Further, the controller 60 may also implement control of a temperature of the heat carrier in the dry cooler 322 or the heat exchanger 31 by controlling a fan speed of the dry cooler 322, controlling a flow rate of the heat carrier in the external pipeline network 300, or the like.

In an embodiment, as shown in FIG. 6, the composite refrigeration system 100 of this embodiment is also provided with the temperature sensor 70. The temperature sensor 70 is disposed in the equipment room 200 of the data center and is configured to monitor a temperature in the equipment room 200 of the data center. The temperature sensor 70 is communicatively connected to the controller 60 to transmit a detected temperature value of the equipment room 200 of the data center to the controller 60. After receiving the temperature value, the controller 60 may control the second three-way valve 52 to distribute a flow quantity of the heat carrier. In some embodiments, the controller 60 may be alternatively communicatively connected to the server 201 in the equipment room 200 of the data center for monitoring a real-time workload of the server 201 and then controlling flow distribution of a heat carrier in the second three-way valve 52 based on the workload. The controller 60 may alternatively receive the temperature value obtained through monitoring by the temperature sensor 70 and workload data of the server 201 at the same time, and distribute a flow quantity of the heat carrier, to ensure a refrigerating effect of the composite refrigeration system 100 and a heating effect on the heat carrier at the same time. In some embodiments, the second three-way valve 52 may be alternatively replaced with two solenoid valves. For related implementations, refer to descriptions of the embodiments in FIG. 1 to FIG. 5. Details are not described again.

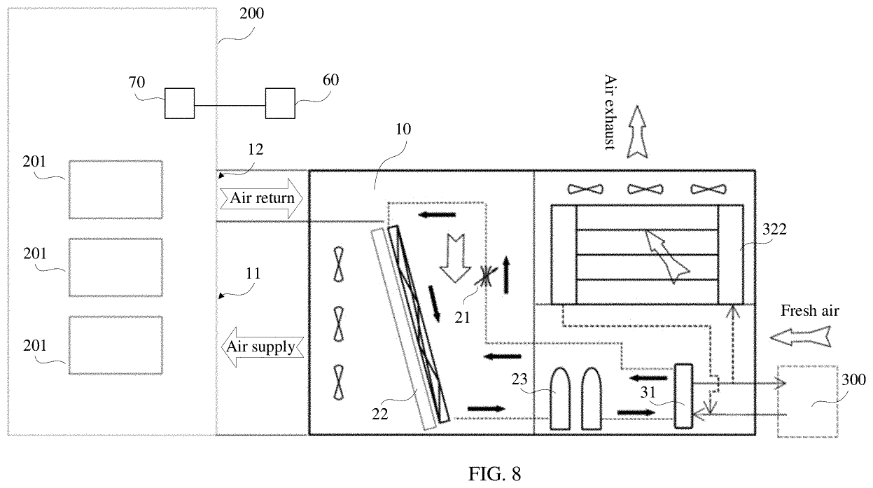

Therefore, referring to FIG. 8, arrangement of the composite refrigeration system 100 in an operation scenario is similar to arrangement in the operation scenario shown in FIG. 1 in an embodiment in which the cooler 32 is the dry cooler 322. A difference lies in a change in a connection manner of the heat exchanger 31, the cooler 32, the external pipeline network 300, and the like. In the operation scenario shown in FIG. 1, the heat exchanger 31 is connected in parallel to the condenser 321, and the condenser 321 may directly dissipate heat for the refrigerant. However, in the operation scenario shown in FIG. 8, the dry cooler 322 is connected in parallel to the external pipeline network 300, and the dry cooler 322 dissipates heat for the heat carrier.

In addition, in the illustration of FIG. 8, the dry cooler 322 is disposed in a sealed compartment, and the compartment is provided with at least two air vents, so that external air enters the compartment through one air vent, completes heat exchange with the dry cooler 322, and then flows out from another air vent. It may be understood that the compartment in which the dry cooler 322 is located is separated from the circulating ventilation channel 10, and the external air does not enter the equipment room 200 of the data center through the circulating ventilation channel 10, to ensure environmental cleanliness of the equipment room 200 of the data center.

However, as mentioned above, that the refrigeration part 20 is located in the circulating ventilation channel 10 is represented as follows: The evaporator 22 is disposed in the circulating ventilation channel 10 in the illustration of FIG. 8. Because the evaporator 22 needs to come into contact and exchange heat with air sent into the equipment room 200 of the data center, to perform refrigeration on the air, the evaporator 22 needs to be disposed in the circulating ventilation channel 10, to come into direct contact with the air. However, as shown in FIG. 8, the compressor 23 in the refrigeration part 20 may be located outside the circulating ventilation channel 10. Because the compressor 23 may generate heat during operation, the compressor 23 is disposed outside the circulating ventilation channel 10 to prevent the heat of the compressor 23 from affecting a refrigerating effect of the composite refrigeration system 100. The electronic expansion valve 21 may be disposed inside the circulating ventilation channel 10 or disposed outside the circulating ventilation channel 10 along with the compressor 23, and a location of the electronic expansion valve 21 does not greatly affect the refrigerating effect. The heat exchanger 31 and the compressor 23 may be disposed in the same compartment. Because the heat exchanger 31 achieves a refrigerating effect of the refrigerant by exchanging heat with the external pipeline network 300, the heat generated when the compressor 23 operates does not greatly affect the heat exchanger 31.

Correspondingly, in the illustration of FIG. 1, the condenser 321 may also be disposed in the sealed compartment, and flow of the external air in the compartment is implemented through the two air vents, to achieve a heat dissipation effect of the condenser 321 on the refrigerant. The compartment in which the condenser 321 is located also needs to be separated from the circulating ventilation channel 10, to ensure cleanliness of the equipment room 200 of the data center.

In the illustration of FIG. 1, the evaporator 22 is also disposed in the circulating ventilation channel 10 and is configured to come into direct contact with air in the circulating ventilation channel 10, to implement a refrigerating function of the composite refrigeration system 100. A location of the electronic expansion valve 21, a location of the compressor 23, and a location of the heat exchanger 31 are also similar to the solution shown in FIG. 8. In a process of ensuring normal operation of the composite refrigeration system 100, an integration degree of components in the composite refrigeration system 100 is increased.

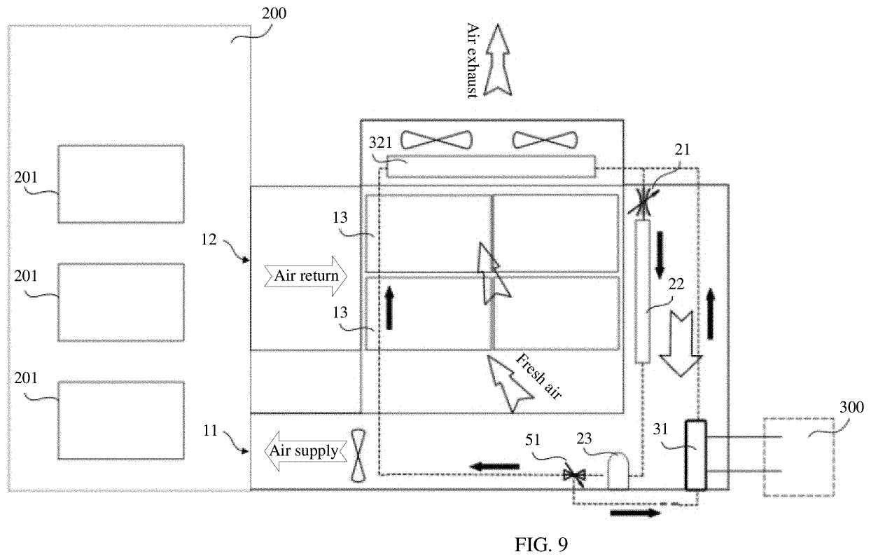

In an embodiment, referring to FIG. 9, a heat exchange core 13 is further disposed in the circulating ventilation channel 10. The heat exchange core 13 and the circulating ventilation channel 10 are sealed and isolated from each other. The heat exchange core 13 is located between the air outlet port 12 and the evaporator 22, and an outdoor ventilation path of the heat exchange core 13 is further connected in series to a ventilation path of the cooler 32. The outdoor ventilation path of the heat exchange core 13 is isolated from a ventilation path of the circulating ventilation channel 10. The outdoor ventilation path of the heat exchange core 13 is used for circulating external air, and forms heat exchange with air in the air outlet port 12 of the circulating ventilation channel 10 through the external air (shown as fresh air in the figure), to further form pre-heat dissipation for air flowing out of the air outlet port 12, thereby reducing a temperature of the air flowing out of the air outlet port 12. In some embodiments, when a temperature of external fresh air is relatively high, a spraying structure may be further disposed at the heat exchange core 13, to perform cooling processing on fresh air passing through the heat exchange core 13, thereby implementing pre-heat dissipation. The pre-heat dissipated air re-flows to the evaporator 22 for refrigeration, and finally enters the equipment room 200 of the data center from the air supply port 11 through the circulating ventilation channel 10.

After pre-heat dissipation of the external air is completed at the heat exchange core 13, the external air enters the cooler 32 (shown as the condenser 321 in FIG. 9), and air-cooled heat dissipation is performed on the cooler 32 (shown as air exhaust in the figure). Because a temperature of air of which pre-heat dissipation is completed at the heat exchange core 13 is lower than a temperature of a refrigerant that needs to be heat dissipated, after the external air enters the heat exchange core 13 to form pre-heat dissipation, a heat dissipation effect of the external air at the condenser 321 may still be ensured. In the embodiment shown in FIG. 9, the external air may successively dissipate heat for air in the circulating ventilation channel 10 and air in the condenser 321, to improve utilization of the external air, reduce a workload of the evaporator 22 accordingly, and also achieve an effect of saving energy.

In this embodiment, because the heat exchange core 13 occupies space, the heat exchanger 31 and the compressor 23 may be alternatively disposed in the circulating ventilation channel 10, to increase an integration degree of the composite refrigeration system 100.

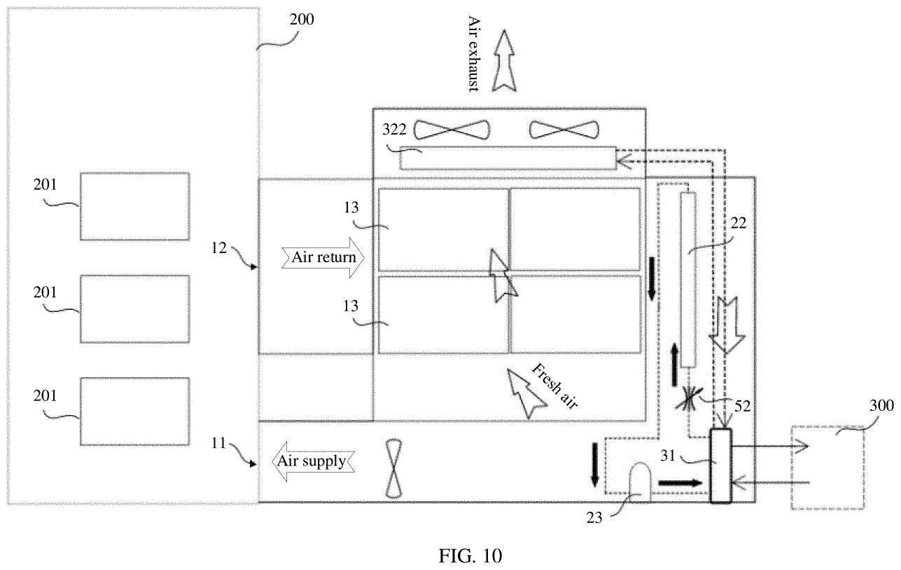

In the embodiment shown in FIG. 10, when the cooler 32 is implemented by using the dry cooler 322, the heat exchange core 13 may be alternatively disposed in the circulating ventilation channel 10. The heat exchange core 13 is also located between the air outlet port 12 and the evaporator 22 and is configured to introduce the external air to perform pre-heat dissipation on air flowing out of the air outlet port 12, to reduce a workload of the evaporator 22, and achieve the effect of saving energy. In addition, the heat exchange core 13 may be connected in series to the dry cooler 322. After heat exchange is completed on the external air at the heat exchange core 13, an air temperature of the external air is lower than a temperature of a heat carrier in the dry cooler 322. Therefore, after pre-heat dissipation of the external air is completed, a heat dissipation effect of the external air at the dry cooler 322 may still be ensured. In other words, in the embodiment shown in FIG. 10, the external air successively dissipates heat for the air in the circulating ventilation channel 10 and the heat carrier in the dry cooler 322, thereby also improving the utilization of the external air.

The foregoing descriptions are merely embodiments, but are not intended as limiting. Any variation or replacement readily figured out by a person skilled in the art within the scope of the embodiments, for example, removing or adding a mechanical part, or changing a shape of a mechanical part, shall fall within the scope of the embodiments. The embodiments and the features in the embodiments can be combined with each other provided that there is no conflict.

1. A composite refrigeration system, comprising:
a refrigeration part connected to an indoor space and configured to use refrigerant to cool air sent into the indoor space;
a heat dissipation part comprising a heat exchanger and a cooler;
a first pipeline connected between the refrigeration part and the heat dissipation part and configured to send the refrigerant from the heat dissipation part to the refrigeration part; and
a second pipeline connected between the refrigeration part and the heat dissipation part and configured to send the refrigerant from the heat dissipation part to the refrigeration part, wherein
there are three heat dissipation modes:
in a first heat dissipation mode, the heat dissipation part is configured to performs air-cooled heat dissipation on the refrigerant by using the cooler alone;
in a second heat dissipation mode, the heat dissipation part is configured to exchanges heat between the refrigerant and a heat carrier in an external pipeline network by using the heat exchanger alone, to perform heat dissipation; and
in a third heat dissipation mode, the heat dissipation part is configured to perform heat dissipation on the refrigerant by simultaneously using the cooler and the heat exchanger.

2. The composite refrigeration system according to claim 1, wherein the cooler is a condenser, the condenser is connected in parallel to the heat exchanger, and the condenser is configured to directly perform air-cooled heat dissipation on the refrigerant.

3. The composite refrigeration system according to claim 2, wherein the composite refrigeration system further comprises:
a controller; and
a first three-way valve, wherein three ports of the first three-way valve are respectively connected to the second pipeline, the heat exchanger, and the condenser, and the controller is configured to controls the first three-way valve to adjust the heat dissipation mode of the heat dissipation part.

4. The composite refrigeration system according to claim 1, wherein the cooler is a dry cooler, the dry cooler is connected in parallel to the external pipeline network, and the dry cooler is configured to perform air-cooled heat dissipation on the heat carrier to implement indirect air-cooled heat dissipation on the refrigerant.

5. The composite refrigeration system according to claim 4, wherein the composite refrigeration system further comprises:
a controller; and
a second three-way valve, three ports of the second three-way valve are respectively connected to the heat exchanger, the external pipeline network, and the dry cooler, and the controller is configured to controls the second three-way valve to adjust the heat dissipation mode of the heat dissipation part.

6. The composite refrigeration system according to claim 3, wherein the composite refrigeration system further comprises:
a temperature sensor, the temperature sensor is disposed in the indoor space and configured to monitor a temperature in the indoor space, the temperature sensor is electrically connected to the controller, and the controller is configured to controls the first three-way valve with reference to a temperature value detected by the temperature sensor.

7. The composite refrigeration system according to claim 5, wherein the composite refrigeration system further comprises:
a temperature sensor, the temperature sensor is disposed in the indoor space and configured to monitor a temperature in the indoor space, the temperature sensor is electrically connected to the controller, and the controller is configured to control the second three-way valve with reference to a temperature value detected by the temperature sensor.

8. The composite refrigeration system according to claim 1, wherein the refrigeration part further comprises:
an electronic expansion valve;
an evaporator; and
a compressor that are sequentially connected, wherein the electronic expansion valve is located on a side of the evaporator that is close to the first pipeline, and the compressor is located on a side of the evaporator that is close to the second pipeline.

9. The composite refrigeration system according to claim 2, wherein the refrigeration part further comprises:
an electronic expansion valve;
an evaporator; and
a compressor that are sequentially connected, wherein the electronic expansion valve is located on a side of the evaporator that is close to the first pipeline, and the compressor is located on a side of the evaporator that is close to the second pipeline.

10. The composite refrigeration system according to claim 3, wherein the refrigeration part further comprises:
an electronic expansion valve;
an evaporator; and
a compressor that are sequentially connected, the electronic expansion valve is located on a side of the evaporator that is close to the first pipeline, and the compressor is located on a side of the evaporator that is close to the second pipeline.

11. The composite refrigeration system according to claim 4, wherein the refrigeration part further comprises:
an electronic expansion valve;
an evaporator; and
a compressor that are sequentially connected, the electronic expansion valve is located on a side of the evaporator that is close to the first pipeline, and the compressor is located on a side of the evaporator that is close to the second pipeline.

12. The composite refrigeration system according to claim 5, wherein the refrigeration part further comprises:
an electronic expansion valve;
an evaporator; and
a compressor that are sequentially connected, the electronic expansion valve is located on a side of the evaporator that is close to the first pipeline, and the compressor is located on a side of the evaporator that is close to the second pipeline.

13. The composite refrigeration system according to claim 6, wherein the refrigeration part further comprises:
an electronic expansion valve;
an evaporator; and
a compressor that are sequentially connected, the electronic expansion valve is located on a side of the evaporator that is close to the first pipeline, and the compressor is located on a side of the evaporator that is close to the second pipeline.

14. The composite refrigeration system according to claim 1, further comprising:
a circulating ventilation channel, wherein an air supply port and an air outlet port of the circulating ventilation channel are separately connected to the indoor space, and the refrigeration part is disposed in the circulating ventilation channel and is configured to refrigerate air flowing out of the air outlet port and send refrigerated air into the indoor space through the air supply port.

15. The composite refrigeration system according to claim 2, further comprising:
a circulating ventilation channel, wherein an air supply port and an air outlet port of the circulating ventilation channel are separately connected to the indoor space, and the refrigeration part is disposed in the circulating ventilation channel and is configured to refrigerate air flowing out of the air outlet port and send refrigerated air into the indoor space through the air supply port.

16. The composite refrigeration system according to claim 3, further comprising:
a circulating ventilation channel, wherein an air supply port and an air outlet port of the circulating ventilation channel are separately connected to the indoor space, and the refrigeration part is disposed in the circulating ventilation channel and is configured to refrigerate air flowing out of the air outlet port and send refrigerated air into the indoor space through the air supply port.

17. The composite refrigeration system according to claim 4, further comprising:
a circulating ventilation channel, wherein an air supply port and an air outlet port of the circulating ventilation channel are separately connected to the indoor space, and the refrigeration part is disposed in the circulating ventilation channel and is configured to refrigerate air flowing out of the air outlet port and send refrigerated air into the indoor space through the air supply port.

18. The composite refrigeration system according to claim 14, wherein a heat exchange core is further disposed in the circulating ventilation channel, the heat exchange core is located between the air outlet port and the refrigeration part, external air flows at the heat exchange core, and the heat exchange core is configured to introduce the external air to perform pre-refrigeration on the air flowing out of the air outlet port.

19. A data center, comprising
an equipment room; and
a composite refrigeration system, comprising
a refrigeration part connected to indoor space of the equipment room and configured to use refrigerant to cool air sent into the indoor space of the equipment room,
a heat dissipation part comprising a heat exchanger and a cooler,
a first pipeline connected between the refrigeration part and the heat dissipation part and configured to send the refrigerant from the heat dissipation part to the refrigeration part, and
a second pipeline connected between the refrigeration part and the heat dissipation part, and configured to send the refrigerant from the refrigeration part to the heat dissipation part, wherein
there are three heat dissipation modes:
in a first heat dissipation mode, the heat dissipation part is configured to performs air-cooled heat dissipation on the refrigerant by using the cooler alone;
in a second heat dissipation mode, the heat dissipation part is configured to exchanges heat between the refrigerant and a heat carrier in an external pipeline network by using the heat exchanger alone, to perform heat dissipation; and
in a third heat dissipation mode, the heat dissipation part is configured to performs heat dissipation on the refrigerant by simultaneously using the cooler and the heat exchanger.

20. The data center according to claim 19, wherein the composite refrigeration system comprises:
a controller, a server is disposed in the equipment room, the controller is communicatively connected to the server, and the controller is configured to control a heat dissipation mode of the composite refrigeration system with reference to a workload of the server.
